(19) United States
(12) Patent Application Publication
(10) Pub. No.: US 2025/0183618 A1
(43) Pub. Date: Jun. 5, 2025

(54) EDGE-EMITTING SEMICONDUCTOR LASER DIODE

(71) Applicant: ams-OSRAM International GmbH, Regensburg (DE)

(72) Inventors: Matthias HEIDEMANN, Regenstauf (DE); Christoph EICHLER, Donaustauf (DE)

(73) Assignee: ams-OSRAM International GmbH, Regensburg (DE)

(21) Appl. No.: 18/840,407

(22) PCT Filed: Dec. 21, 2022
(86) PCT No.: PCT/EP2022/087230

§ 371 Date: Aug. 21, 2024

(30) Foreign Application Priority Data
Feb. 24, 2022 (DE) 10 2022 104 418.1

(51) Int. Cl. H01S 5/065

(52) U.S. Cl. CPC H01S 5/0653

(57) ABSTRACT

The invention relates to an edge-emitting semiconductor laser diode including a substrate having a first main face and a second main face opposite the first main face, an epitaxial semiconductor layer stack on the first main face of the substrate, wherein the epitaxial semiconductor layer stack includes an active layer for generating electromagnetic radiation, a matching layer arranged on the second main face of the substrate, and an absorption layer applied directly to the matching layer and configured to at least partially absorb the electromagnetic radiation, wherein the substrate and the matching layer are transparent to electromagnetic radiation generated during operation, and the matching layer is configured to increase the absorption of electromagnetic radiation in the absorption layer.

### CROSS-REFERENCE TO RELATED APPLICATIONS

The present application is a national stage entry from International Application No. PCT/EP2022/087230, filed on Dec. 21, 2022, published as International Publication No. WO 2023/160865 A1 on Aug. 31, 2023, and claims priority to German Patent Application No. 10 2022 104 418.1, filed Feb. 24, 2022, the disclosures of all of which are hereby incorporated by reference in their entireties.

### FIELD

An edge-emitting semiconductor laser diode is specified.

### BACKGROUND

An edge-emitting semiconductor laser diode comprising an improved beam quality is to be specified. This object is solved by the device with the features of the independent patent claim.

Advantageous embodiments and further developments of the edge-emitting semiconductor laser diode are specified in the dependent claims.

### SUMMARY

According to an embodiment, the edge-emitting semiconductor laser diode comprises a substrate with a first main surface and a second main surface opposite to the first main surface. The substrate is, for example, a growth substrate or a carrier substrate. In particular, the substrate is configured for mechanically stabilizing the edge-emitting semiconductor laser diode. The main surfaces preferably comprise a larger surface area than side surfaces of the substrate.

The substrate comprises, for example, gallium nitride, sapphire, silicon, silicon carbide or gallium arsenide or consists of one of these materials.

According to a further embodiment, the edge-emitting semiconductor laser diode comprises an epitaxial semiconductor layer stack on the first main surface of the substrate, wherein the epitaxial semiconductor layer stack comprises an active layer for generating electromagnetic radiation. For example, the epitaxial semiconductor layer stack is epitaxially grown on the first main surface of the substrate. A main extension plane of layers of the epitaxial semiconductor layer stack is preferably arranged parallel to the first main surface of the substrate.

The epitaxial semiconductor layer stack preferably comprises a III-V compound semiconductor material or consists of a III-V compound semiconductor material. A III-V compound semiconductor material comprises at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example a nitride compound semiconductor material.

Nitride compound semiconductor materials are compound semiconductor materials that contain nitrogen, such as the materials from the system InₓAl_{y}Ga_{1-x-y}N with 0≤x≤1, 0≤y≤1 and x+y≤1.

The active layer preferably comprises a pn-junction, a double heterostructure, a single quantum well or particularly preferably a multiple quantum well structure (MQW) for generating radiation. The term quantum well structure does not indicate the dimensionality of the quantization. It therefore includes quantum wells, quantum wires and quantum dots and any combination of these structures. For example, the active layer is configured for generating electromagnetic radiation in a spectral range between infrared and ultraviolet light.

According to a further embodiment of the edge-emitting semiconductor laser diode, the substrate and the epitaxial semiconductor layer stack applied thereto comprise two opposing facets. In particular, the facets are side surfaces of the substrate and of the epitaxial semiconductor layer stack and are arranged perpendicular or inclined to the first main surface of the substrate, for example.

A highly reflective layer is preferably arranged on a facet, which is referred to below as back side facet, which is configured for reflecting electromagnetic radiation generated during operation. For example, the highly reflective layer reflects at least 90%, preferably at least 99%, of the electromagnetic radiation incident thereon and generated during operation.

The facet opposite the back side facet is referred to below as the light outcoupling facet. The light outcoupling facet is configured for coupling electromagnetic radiation generated during operation out of the edge-emitting laser diode. An anti-reflective layer is preferably arranged on the light outcoupling facet, which has a lower reflectivity than the highly reflective layer on the back side facet. For example, the anti-reflective layer reflects between 10% and 80%, inclusive, of the electromagnetic radiation incident thereon and generated during operation.

In particular, the back side facet and the light outcoupling facet, together with the layers applied to them, form an optical resonator. The optical resonator can also include additional optical elements, such as external mirrors. Electromagnetic radiation generated in the active layer during operation forms a standing electromagnetic wave in the optical resonator.

In conjunction with the optical resonator, the active layer is configured for generating electromagnetic laser radiation. Electromagnetic laser radiation is generated by stimulated emission and, in contrast to electromagnetic radiation which is generated by spontaneous emission, generally has a very high coherence length, a very narrow spectral linewidth and/or a high degree of polarization.

According to a further embodiment, the edge-emitting semiconductor laser diode comprises at least one matching layer arranged on the second main surface of the substrate. For example, the matching layer is applied directly to the second main surface of the substrate. The matching layer preferably comprises a dielectric material or a semiconductor material, or consists of one of these materials. The edge-emitting laser diode can also comprise multiple matching layers.

According to a further embodiment, the edge-emitting semiconductor laser diode comprises an absorption layer disposed directly on the matching layer and configured for absorbing the electromagnetic radiation generated during operation at least partially. The absorption layer is preferably applied to a side of the matching layer facing away from the substrate and covers the matching layer completely or partially. In particular, the absorption layer is configured for at least partially absorbing electromagnetic laser modes propagating in the substrate. For example, the absorption layer comprises an absorption coefficient of at least 100 cm⁻¹, preferably of at least 1000 cm⁻¹, for electromagnetic radiation generated during operation.

According to a further embodiment of the edge-emitting semiconductor laser diode, the substrate and the matching layer are transparent to electromagnetic radiation generated during operation. In particular, a band gap of the substrate and a band gap of the matching layer are larger than a band gap of the active layer of the epitaxial semiconductor layer stack. For example, the substrate and the matching layer comprise transmittances for electromagnetic radiation generated during operation of at least 5%, preferably of at least 10%, and particularly preferably of at least 50%.

According to a further embodiment of the edge-emitting semiconductor laser diode, the matching layer is configured for increasing the absorption of electromagnetic radiation in the absorption layer. In particular, the matching layer is configured for adjusting a phase and a position of intensity maxima of laser modes propagating in the substrate in such a way that these laser modes experience strong attenuation by the absorption layer. For example, the attenuation of the laser modes propagating in the substrate in an edge-emitting semiconductor laser diode with the matching layer is at least one order of magnitude larger, preferably at least two orders of magnitude larger, than in an otherwise identical edge-emitting semiconductor laser diode without the matching layer.

According to a preferred embodiment, the edge-emitting semiconductor laser diode comprises at least the following features:
a substrate with a first main surface and a second main surface opposite to the first main surface,
an epitaxial semiconductor layer stack on the first main surface of the substrate, wherein the epitaxial semiconductor layer stack comprises an active layer for generating electromagnetic radiation,
a matching layer arranged on the second main surface of the substrate, and
an absorption layer disposed directly on the matching layer and configured for absorbing the electromagnetic radiation at least partially, wherein
the substrate and the matching layer are transparent to electromagnetic radiation generated during operation, and
the matching layer is configured for increasing the absorption of electromagnetic radiation in the absorption layer.

In edge-emitting semiconductor laser diodes, layers of the epitaxial semiconductor layer stack are arranged in particular such that the electromagnetic radiation generated during operation is guided therein and outcoupled at the light outcoupling facet. For example, the active layer is arranged between two cladding layers that are configured for guiding the electromagnetic radiation laterally. Lateral here and in the following refers to a direction parallel to the first main surface of the substrate.

Due to scattering from roughness and/or defects and/or because the cladding layers are too thin, some of the electromagnetic radiation generated during operation can couple from the semiconductor layer stack into the substrate. Electromagnetic laser modes thus propagate in a transparent substrate, whereby the substrate can act as a waveguide for these laser modes. These electromagnetic laser modes propagating in the substrate, which are also referred to below as substrate modes, can also be coupled out at the light outcoupling facet of the edge-emitting semiconductor laser diode. The substrate modes lead, for example, to additional intensity peaks in a far field of the laser radiation generated during operation. In particular, the substrate modes impair the beam quality and thus the imaging and/or image quality of a laser beam outcoupled from the edge-emitting semiconductor laser diode.

The edge-emitting semiconductor laser diode described herein is based on the idea of suppressing these substrate modes by applying suitable layers on a main surface of the substrate opposite the epitaxial semiconductor layer stack.

For example, substrate modes are at least partially absorbed by the absorption layer. However, strongly absorbing absorption layers, for example metallic absorption layers, can comprise a high reflectivity. As a result, substrate modes are in particular reflected at the interface to the absorption layer, which can limit and/or hinder the suppression of substrate modes by the absorption layer.

The matching layer adjusts a phase and a position of intensity maxima of the substrate modes in particular such that the substrate modes are strongly attenuated by the absorption layer. For example, the attenuation of the substrate modes in a semiconductor laser diode with the matching layer is two orders of magnitude larger than in an otherwise identical semiconductor laser diode without the matching layer. The matching layer is preferably transparent to electromagnetic radiation generated during operation and, in particular, comprises a higher refractive index than the substrate. Substrate modes that couple into the matching layer and are reflected at the absorption layer are thus, for example, totally reflected at an interface between the matching layer and substrate and deflected back towards the absorption layer. In particular, this can increase the absorption of electromagnetic radiation in the absorption layer.

In combination with the absorption layer, the matching layer enables a simple and cost-effective suppression of parasitic substrate modes. In particular, this increases the beam quality of the edge-emitting laser diode, resulting in improved imaging and image quality.

According to a further embodiment of the edge-emitting semiconductor laser diode, the substrate is a growth substrate for the epitaxial semiconductor layer stack. In particular, the epitaxial semiconductor layer stack is epitaxially grown on the substrate.

According to a further embodiment of the edge-emitting semiconductor laser diode, the matching layer reduces a distance between the absorption layer and an intensity maximum of electromagnetic laser modes propagating in the substrate. In other words, the matching layer is configured for bringing the intensity maxima of a plurality of electromagnetic laser modes propagating in the substrate closer to the absorption layer. By reducing the distance between the intensity maxima and the absorption layer, the absorption of the laser modes propagating in the substrate is advantageously increased.

Preferably, this effect of the matching layer is not limited to individual, selected substrate modes. Rather, the matching layer acts on a large part of the electromagnetic laser modes propagating in the substrate.

According to a further embodiment of the edge-emitting semiconductor laser diode, the matching layer reduces a reflection of electromagnetic laser modes propagating in the substrate at the absorption layer. In particular, this increases the absorption of electromagnetic laser modes propagating in the substrate by the absorption layer. For example, a thickness of the absorption layer is set such that a portion of a plurality of substrate modes reflected at the interface between the substrate and the matching layer interferes as destructively as possible with a portion of these substrate modes reflected at an interface between the matching layer and the absorption layer.

According to a further embodiment of the edge-emitting semiconductor laser diode, a refractive index of the matching layer for electromagnetic radiation generated during operation is larger than a refractive index of the substrate for electromagnetic radiation generated during operation. Thus, electromagnetic laser radiation propagating in the substrate can be coupled into the matching layer, while electromagnetic laser radiation propagating in the matching layer can be totally reflected at the interface to the substrate. In particular, this increases the attenuation of substrate modes by the absorption layer.

For example, the refractive index of the matching layer is larger than the refractive index of the substrate by at least 0.01 and by at most 5. Preferably, the refractive index of the matching layer is larger than the refractive index of the substrate by at least 0.1 and by at most by 1.5. Particularly preferably, the refractive index of the matching layer is larger than the refractive index of the substrate by at least 0.15 and by at most 0.7.

According to a further embodiment of the edge-emitting semiconductor laser diode, an extinction coefficient of the matching layer for electromagnetic radiation generated during operation is at most 2. Preferably, the extinction coefficient of the matching layer is at most 0.7 and particularly preferably at most 0.1. The lower the extinction coefficient of the matching layer, the more transparent the matching layer is for electromagnetic radiation generated during operation.

According to a further embodiment of the edge-emitting semiconductor laser diode, a thickness of the matching layer is proportional to a wavelength of electromagnetic radiation generated during operation and inversely proportional to a refractive index of the matching layer for electromagnetic radiation generated during operation. Here and in the following, the thickness of a layer denotes a spatial extension in a direction perpendicular to the second main surface of the substrate.

According to a further embodiment of the edge-emitting semiconductor laser diode, a thickness of the matching layer is D=D₀+m*Δd with a tolerance of ±30 nanometers. Here,

$${D}_{0} = \frac{λ}{450 * ( 0.00192 * {n}^{2} + 0.01873 * n - 0.05235 )} ,$$

$$Δ d = \frac{λ}{\sqrt[2]{{n}^{2} - {n}_{Substrate}^{2}}}$$

and m denotes an integer larger than or equal to zero, wherein λ denotes the wavelength of electromagnetic radiation generated during operation, n denotes the refractive index of the matching layer for electromagnetic radiation generated during operation and n_{Substrate} denotes the refractive index of the substrate for electromagnetic radiation generated during operation. Preferably, m is zero and thus D=D₀. The above formula for the thickness of the matching layer applies only to matching layers with a refractive index larger than about 2.5 and larger than the refractive index of the substrate.

By selecting the thickness of the matching layer according to the above formula, the attenuation of electromagnetic laser modes propagating in the substrate can be advantageously increased. For example, the thickness of the matching layer specified above reduces the strength of the substrate modes by three to four orders of magnitude compared to a corresponding edge-emitting semiconductor laser diode without a matching layer.

According to a further embodiment of the edge-emitting semiconductor laser diode, the matching layer comprises a lateral structuring such that only a part of the second main surface of the substrate is covered by the matching layer and/or the matching layer comprises at least two segments separated from each other and/or the matching layer comprises at least one cut-out. In the case that the matching layer is electrically insulating, a lateral structuring of the matching layer is advantageous, in particular, for an electrical contacting of the epitaxial semiconductor layer stack via the second main surface of the substrate.

According to a further embodiment of the edge-emitting semiconductor laser diode, the matching layer comprises titanium oxide, non-stoichiometric silicon oxide, non-stoichiometric silicon nitride, silicon carbide or gallium phosphide, or consists of one of these materials.

According to a further embodiment, the edge-emitting semiconductor laser diode comprises at least two matching layers arranged between the second main surface of the substrate and the absorption layer. The matching layers can comprise different materials or different material compositions. This can improve attenuation and thus suppression of electromagnetic laser modes propagating in the substrate.

According to a further embodiment of the edge-emitting semiconductor laser diode, the matching layer is electrically conductive. Accordingly, the epitaxial semiconductor layer stack can be electrically contacted, in particular, via an electrically conductive absorption layer, the electrically conductive matching layer and via an electrically conductive substrate.

According to a further embodiment of the edge-emitting semiconductor laser diode, the absorption layer is configured as a contact layer for electrical contacting of the epitaxial semiconductor layer stack. In particular, the absorption layer is electrically conductive. As a result, process steps in producing the edge-emitting semiconductor laser diode can be saved and costs reduced.

According to a further embodiment of the edge-emitting semiconductor laser diode, the absorption layer comprises a metal, a semiconductor material or a non-stoichiometric dielectric or consists of one of these materials.

According to a further embodiment, the edge-emitting semiconductor laser diode additionally comprises a light blocking layer arranged on a sub-region of the light outcoupling facet of the semiconductor laser diode and configured for at least partially absorbing and/or reflecting electromagnetic laser modes propagating in the substrate. The light blocking layer is preferably arranged on a sub-region of the light outcoupling facet which comprises the substrate. In particular, the light outcoupling facet remains free of the light blocking layer in a region of the active layer.

The light blocking layer can comprise several sub-layers or consist of several sub-layers. For example, a transmission of the light blocking layer for electromagnetic radiation generated during operation is at most 20%. The light blocking layer comprises, in particular, an oxide, an oxynitride, or a metal, for example aluminum oxide, silicon oxynitride, titanium, platinum or chromium, or consists of one of these materials.

According to a further embodiment, the edge-emitting semiconductor laser diode comprises a contact layer which is applied to the absorption layer and is configured for electrical contacting of the epitaxial semiconductor layer stack. Preferably, the contact layer is arranged directly on the absorption layer. The contact layer comprises, for example, a metal or is formed from a metal. The contact layer is configured for electrical contacting of the epitaxial semiconductor layer stack via the second main surface of the substrate.

Alternatively or additionally, the contact layer can also be arranged on the first main surface of the substrate. A further contact layer is arranged, for example, on a main surface of the epitaxial semiconductor layer stack facing away from the substrate.

According to a further embodiment of the edge-emitting semiconductor laser diode, the active layer comprises at least two emission regions arranged laterally next to each other, which are configured for generating electromagnetic radiation in different wavelength ranges. For example, the emission regions arranged next to each other comprise different material compositions and thus different band gaps. Preferably, the emission regions can be electrically contacted independently of one another and can therefore be operated and/or controlled independently of one another. The emission regions of the active layer arranged next to each other can also generate electromagnetic radiation in the same wavelength range. For example, the edge-emitting semiconductor laser diode formed as a laser bar.

According to a further embodiment of the edge-emitting semiconductor laser diode, the matching layer comprises at least two sub-regions arranged laterally next to each other, wherein one sub-region each is arranged in a direction perpendicular to the first main surface of the substrate under an emission region, respectively. In particular, each emission region of the active layer comprises a corresponding sub-region of the matching layer on the opposite main surface of the substrate. The sub-regions of the matching layer can be connected to each other or spatially separated from each other.

According to a further embodiment of the edge-emitting semiconductor laser diode, the sub-regions of the matching layer comprise different materials and/or different thicknesses. In the case that the active layer comprises several emission regions which are configured for generating electromagnetic radiation in different wavelength ranges, the thickness of the matching layer in the different sub-regions can, for example, be selected to match an emitter wavelength of the individual emission regions, respectively.

Further advantageous embodiments and further developments of the edge-emitting semiconductor laser diode are apparent from the exemplary embodiments described below in conjunction with the figures.

### BRIEF DESCRIPTION OF THE DRAWINGS

FIGS. 1 and 2 show profiles of electromagnetic laser radiation in the far field of an edge-emitting semiconductor laser diode.

FIGS. 3, 4 and 5 show various schematic representations of an edge-emitting semiconductor laser diode according to an exemplary embodiment.

FIGS. 6 and 7 show schematic representations of a mode strength of substrate modes as a function of a thickness of the matching layer.

FIG. 8 shows a schematic representation of a thickness of the matching layer as a function of a refractive index of the matching layer.

FIG. 9 shows a schematic representation of a mode strength of substrate modes as a function of a refractive index of the matching layer.

FIG. 10 shows a schematic representation of a mode strength of substrate modes as a function of an extinction coefficient of the matching layer.

FIGS. 11 to 15 show schematic sectional views of edge-emitting semiconductor laser diodes according to further exemplary embodiments.

FIGS. 16 to 23 show schematic top views of the second main surface of the substrate of edge-emitting semiconductor laser diodes according to various exemplary embodiments.

FIGS. 24 to 26 show schematic sectional views of edge-emitting semiconductor laser diodes according to further exemplary embodiments.

FIG. 27 shows a schematic representation of the intensity of substrate modes according to an exemplary embodiment.

### DETAILED DESCRIPTION

Elements that are identical, similar or have the same effect are marked with the same reference sign in the figures. The figures and the proportions of the elements shown in the figures are not to be regarded as true to scale. Rather, individual elements, in particular layer thicknesses, may be shown exaggeratedly large for better visualization and/or understanding.

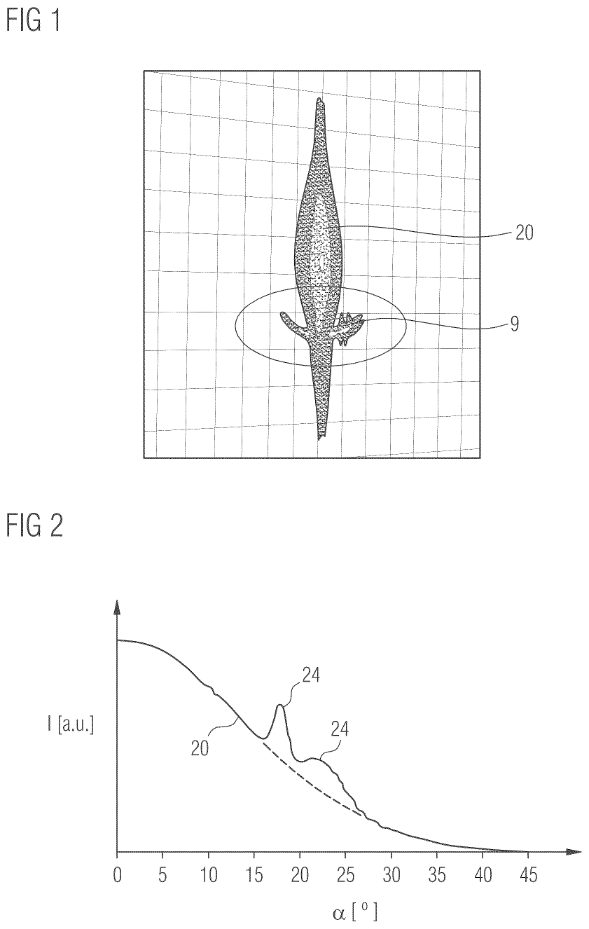

FIG. 1 shows a cross-section of the laser beam emitted by the edge-emitting laser diode. In particular, the electromagnetic laser beam comprises a Gaussian mode profile 20 with different mode widths in two mutually orthogonal directions. The area marked with an ellipse shows additional structures in the outcoupled laser beam, which are caused by electromagnetic laser modes 9 propagating in the substrate 1. These substrate modes 9 are at least partially coupled out of the edge-emitting semiconductor laser diode, impair the beam quality and lead, for example, to poorer imaging quality.

FIG. 2 shows a mode profile 20 of electromagnetic laser radiation in the far field of an edge-emitting semiconductor laser diode, where the intensity I of the electromagnetic laser radiation is shown as a function of a radiation angle α. In particular, the electromagnetic laser radiation comprises a Gaussian mode profile 20. Furthermore, the mode profile 20 shows additional intensity peaks 24 of the electromagnetic laser radiation, which are caused by electromagnetic laser modes 9 propagating in the substrate 1 and are coupled out of the edge-emitting semiconductor laser diode. The edge-emitting semiconductor laser diode described here is based on the idea of largely suppressing these additional intensity peaks 24.

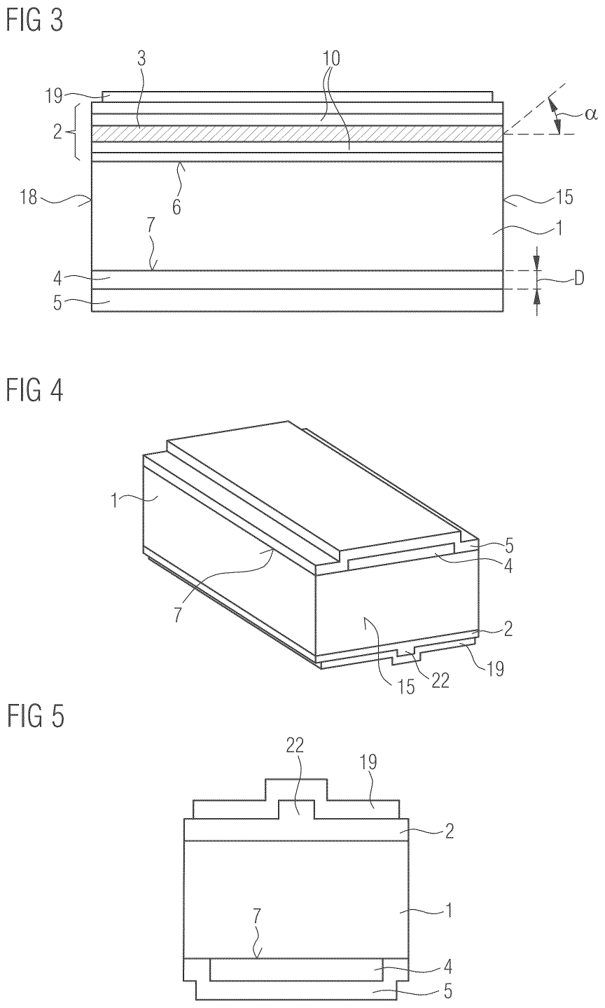

The edge-emitting semiconductor laser diode according to the exemplary embodiment of FIG. 3 comprises a substrate 1 with an epitaxial semiconductor layer stack 2 applied thereon. The epitaxial semiconductor layer stack 2 is applied to a first main surface 6 of the substrate 1 and comprises, for example, a nitride compound semiconductor material. The epitaxial semiconductor layer stack 2 comprises an active layer 3 for generating electromagnetic radiation. Furthermore, the epitaxial semiconductor layer stack 2 comprises cladding layers 10 for guiding the electromagnetic laser radiation generated during operation in the active layer 3, wherein the active layer 3 is arranged between two cladding layers 10.

The substrate 1 is, in particular, a growth substrate on which the epitaxial semiconductor layer stack 2 is epitaxially grown. For example, the substrate 1 comprises gallium nitride or silicon carbide or consists of one of these materials. The substrate 1 is transparent for electromagnetic laser radiation generated during operation. In particular, the substrate 1 comprises a larger band gap than the active layer 3 of the epitaxial semiconductor layer stack 2. Electromagnetic laser radiation generated during operation can thus at least partially couple from the active layer 3 into the transparent substrate 1 and propagate in the substrate 1 as electromagnetic laser mode 9.

A matching layer 4 is applied directly to the second main surface 7 of the substrate 1. The matching layer 4 comprises a dielectric material or a semiconductor material that is transparent to electromagnetic radiation generated during operation. For example, the matching layer 4 comprises gallium phosphide or consists of gallium phosphide. In particular, a refractive index n of the matching layer 4 for electromagnetic radiation generated during operation is larger than a refractive index of the substrate 1. For example, the refractive index n of the matching layer 4 is larger than the refractive index of the substrate 1 by at least 0.15 and by at most 0.7. Furthermore, the extinction coefficient k of the matching layer is preferably at most 0.1.

An absorption layer 5 is applied directly to the main surface of the matching layer 4 opposite to the substrate 1. The absorption layer 5 has, in particular, a high absorption coefficient for electromagnetic radiation generated during operation and is formed, for example, from a metal.

A thickness D of the matching layer 4 is selected such that substrate modes 9 are absorbed as strongly as possible by the absorption layer 5 and are thus attenuated. For example, the matching layer 4 reduces a reflection of substrate modes 9 at the absorption layer 5. The thickness D of the matching layer 4 is, in particular, proportional to the wavelength of electromagnetic radiation generated during operation and inversely proportional to a refractive index n of the matching layer.

A contact layer 19 for electrical contacting of the active layer 3 is arranged on a main surface of the epitaxial semiconductor layer stack 2 opposite to the substrate 1. Furthermore, the absorption layer 5 is configured as a further contact layer for making electrical contact with the active layer 3, wherein the substrate 1 is electrically conductive. For example, the substrate comprises a doped semiconductor material. The matching layer 4 arranged between the substrate 1 and the absorption layer 5 is either electrically conductive or comprises a lateral structuring 11. Examples of lateral structuring 11 of the matching layer 4 are shown in FIGS. 16 to 23. Due to the lateral structuring 11 of the matching layer 4, the edge-emitting semiconductor laser diode comprises, in particular, a direct, electrically conductive connection between the absorption layer 5 and the substrate 1.

Opposite side surfaces of the semiconductor laser diode are formed as light outcoupling facet 15 and back side facet 18, which together form an optical resonator of the edge-emitting semiconductor laser diode. In conjunction with the active layer 3, the optical resonator is configured for generating electromagnetic laser radiation during operation. The electromagnetic laser radiation is coupled out via the light outcoupling facet 15 and is emitted from the edge-emitting semiconductor laser diode at the radiation angle α. The radiation angle α denotes an angle between a surface normal of the light outcoupling facet 15 and a radiation direction of the electromagnetic laser radiation generated during operation.

FIG. 4 shows a schematic perspective view of the edge-emitting semiconductor laser diode according to the exemplary embodiment of FIG. 3. In particular, the epitaxial semiconductor layer stack 2 comprises a ridge waveguide 22 for guiding electromagnetic radiation generated during operation. The ridge waveguide 22 extends in the lateral direction between the light outcoupling facet 15 and the opposite back side facet 18. The contact layer 19 for electrical contacting of the active layer 3 completely covers the ridge waveguide 22.

The matching layer 4 only partially covers the second main surface 7 of the substrate 1. In particular, a region of the second main surface 7 in a perpendicular direction above the ridge waveguide 22 is covered by the matching layer 4. Here, the matching layer 4 covers a region of the second main surface 7 which extends beyond the ridge waveguide 22 in a lateral direction perpendicular to a main extension direction of the ridge waveguide 22 preferably by at least 30 micrometers, particularly preferably by at least 60 micrometers. Regions of the second main surface 7 that are not covered by the matching layer 4 are covered by the absorption layer 5, which extends over the entire second main surface 7. The absorption layer 5 is thus in direct electrical contact with the electrically conductive substrate 1 and is configured for electrical contacting the semiconductor layer stack 2.

FIG. 5 shows a schematic sectional view of the edge-emitting semiconductor laser diode according to the exemplary embodiment of FIG. 3 in plan view of the light outcoupling facet 15. In particular, the matching layer 4 does not completely cover the second main surface 7 of the substrate 1, but protrudes beyond the ridge waveguide 22 by at least 30 micrometers on both sides in the lateral direction.

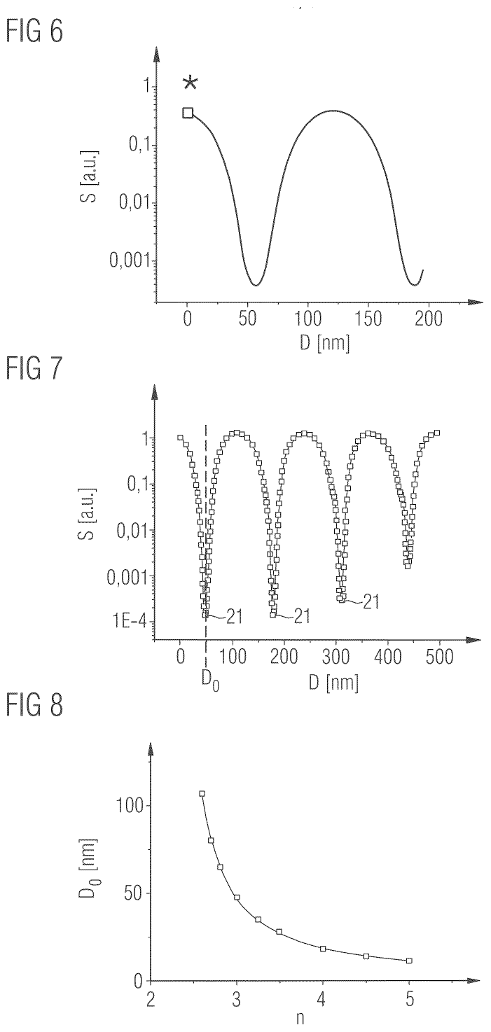

FIG. 6 schematically shows a dependence between a thickness D of the matching layer 4 and a mode strength S of the substrate modes 9. In particular, the mode strength S indicates a relative intensity of the substrate modes 9 coupled out from the semiconductor laser diode. A mode strength S with the value S=1 corresponds to a semiconductor laser diode without absorption layer 5 and is marked with an asterisk in FIG. 4. By contrast, a semiconductor laser diode of the same design with an additional absorption layer 5, but without a matching layer 4, comprises a lower mode strength S, which is marked with a square in FIG. 4.

Furthermore, FIG. 4 shows the mode strength S of substrate modes 9 of a semiconductor laser diode with an absorption layer 5 and a matching layer 4 as a function of the thickness D of the matching layer 4. In particular, FIG. 4 shows that the mode strength S of the substrate modes 9 can be reduced by, for example, two orders of magnitude by a suitable choice of the thickness D of the matching layer 4.

FIG. 7 shows the results of a numerical simulation of the mode strength S of substrate modes 9 as a function of the thickness D of the matching layer 4. The mode strength S comprises several approximately periodic minima 21. The first minimum 21 occurs at a thickness D of the matching layer 4 designated as D₀. Further minima 21 occur approximately at thicknesses D=D₀+m*Δd of the matching layer 4, where

$$Δ d = \frac{λ}{\sqrt[2]{{n}^{2} - {n}_{Substrate}^{2}}}$$

and m is an integer larger than or equal to zero. Here, n and _{nsubstrate} denote refractive indices of the matching layer 4 and the substrate 1 for electromagnetic radiation generated during operation.

FIG. 8 shows the thickness D₀, at which the first minimum 21 of the mode strength S in FIG. 5 occurs, as a function of the refractive index n of the matching layer 4. The thickness D₀ can be approximately parametrized by the function

$${D}_{0} = \frac{λ}{450 * ( 0.00192 * {n}^{2} + 0.01873 * n - 0.05235 )}$$

where λ is the wavelength of electromagnetic radiation generated during operation and n is the refractive index of the matching layer 4.

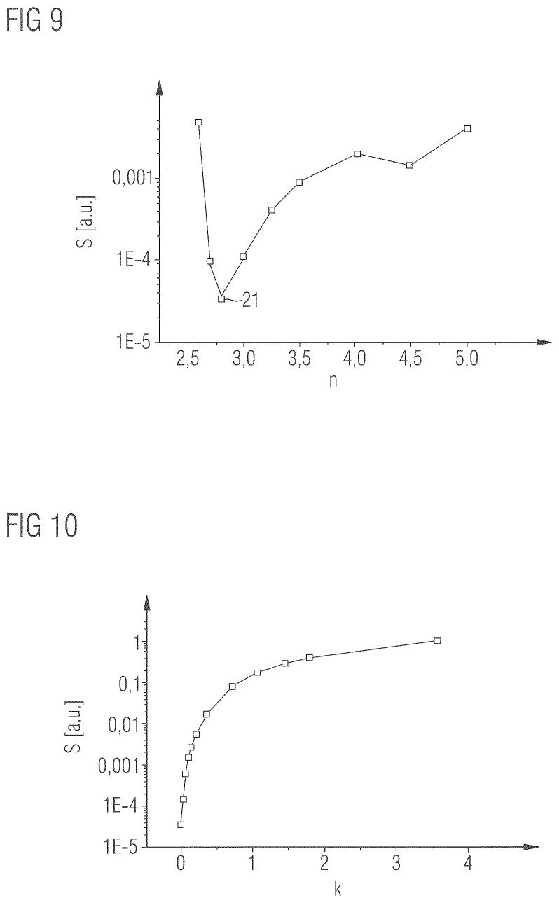

FIG. 9 shows numerical results for the mode strength S of substrate modes 9 as a function of the refractive index n of the matching layer 4, where the thickness D of the matching layer 4 and optical properties of the absorption layer 5 are fixed. In particular, FIG. 7 shows that the mode strength S of the substrate modes 9 comprises a strongly pronounced minimum 21 at a certain value of the refractive index n of the matching layer 4. This value depends, among other things, on the optical properties of the absorption layer 5, in particular on the complex refractive index of the absorption layer 5.

FIG. 10 shows a mode strength S of substrate modes 9 as a function of an extinction coefficient k of the matching layer 4, where the thickness D and the refractive index n of the matching layer 4, as well as optical properties of the absorption layer 5, are fixed. In particular, FIG. 8 shows that the smallest possible extinction coefficient k of the matching layer 4 results in a particularly low mode strength S of the substrate modes 9. In other words, the smallest possible extinction coefficient k of the matching layer 4 leads to an advantageously large attenuation of the substrate modes 9.

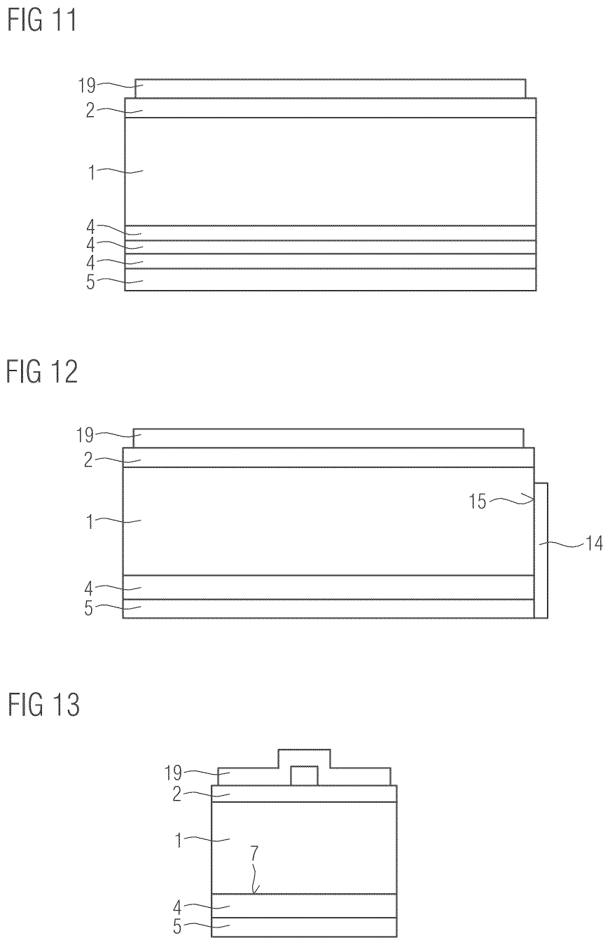

In contrast to the semiconductor laser diode in FIG. 3, the edge-emitting semiconductor laser diode according to the exemplary embodiment of FIG. 11 comprises several matching layers 4 arranged between the substrate 1 and the absorption layer 5. The different matching layers 4 comprise, for example, different materials and thus different optical properties, in particular different refractive indices n. As a result, the attenuation of the substrate modes 9 can be finely adjusted and thus improved.

Compared to the semiconductor laser diode in FIG. 3, the edge-emitting semiconductor laser diode according to the exemplary embodiment of FIG. 12 additionally comprises a light blocking layer 14. The light blocking layer 14 partially covers the light outcoupling facet 15, in particular in the region of the substrate 1. The light blocking layer 14 is configured for an at least partial absorption and/or reflection of substrate modes 9. Thus, an outcoupling of substrate modes 9 from the semiconductor laser diode is at least partially reduced or prevented. In conjunction with the matching layer 4 and the absorption layer 5, substrate modes 9 in the far field of the laser radiation coupled out by the semiconductor laser diode can thus be suppressed even more strongly.

In contrast to the edge-emitting semiconductor laser diode in FIG. 5, the exemplary embodiment in FIG. 13 comprises a matching layer 4 that completely covers the second main surface 7 of the substrate 1. The matching layer 4 is electrically conductive in order to ensure electrical contact between the absorption layer 5 and the epitaxial semiconductor layer stack 2 via the electrically conductive substrate 1.

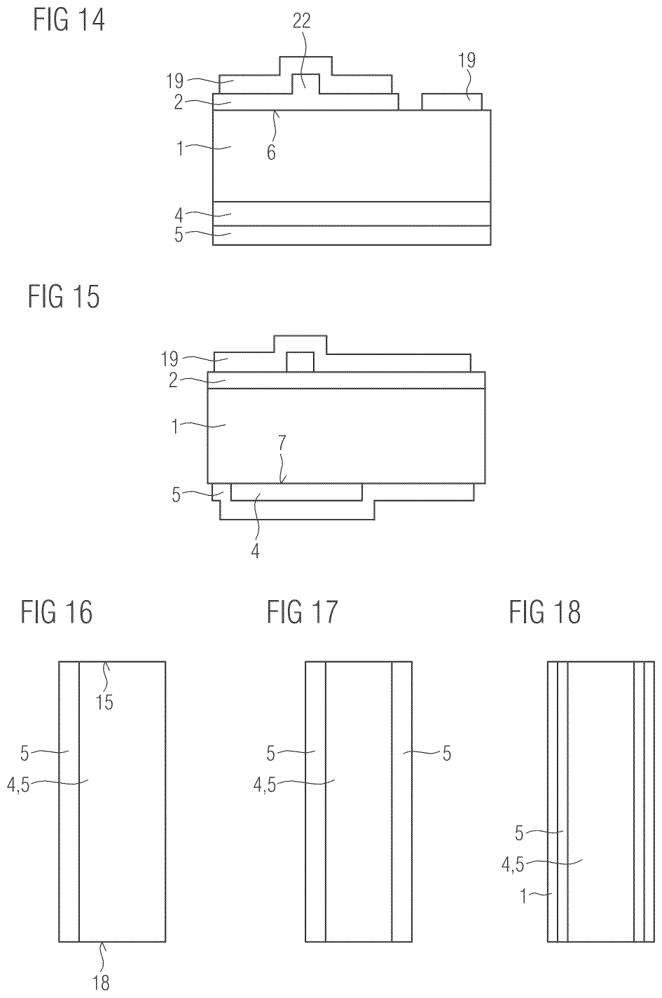

In contrast to the edge-emitting semiconductor laser diode in FIG. 13, in the exemplary embodiment of the edge-emitting semiconductor laser diode in FIG. 14, the absorption layer 5 is not configured as a contact layer. Thus, no electrically conductive matching layer 4 and no electrically conductive substrate 1 are necessary for electrically contacting the epitaxial semiconductor layer stack 2. Instead, the contact layers 19 for electrically contacting the epitaxial semiconductor layer stack 2 are arranged parallel to the ridge waveguide 22 and laterally spaced apart from the epitaxial semiconductor layer stack 2 on the first main surface 6 of the substrate 1, as well as on the main surface of the epitaxial semiconductor layer stack 2 facing away from the substrate 1.

In the edge-emitting semiconductor laser diode according to the exemplary embodiment in FIG. 15, an area in which the absorption layer 5 is in direct contact with the second main surface 7 of the substrate 1 is larger than in the edge-emitting semiconductor laser diode in FIG. 12. As a result, electrical contact between the absorption layer 5 and the substrate 1 can be improved in the case of a non-electrically conductive matching layer 4.

FIG. 16 shows a top view of the second main surface 7 of the substrate 1 of an edge-emitting semiconductor laser diode. Here, the second main surface 7 is partially free of the matching layer 4, while the absorption layer 5 extends over the entire second main surface 7. In particular, an area at the edge of the second main surface 7, which extends between the light outcoupling facet 15 and the back side facet 18, is free of the matching layer 4.

In the edge-emitting semiconductor laser diode in FIG. 17, in contrast to FIG. 16, two areas at opposite edges of the second main surface 7 are free of the matching layer 4.

In contrast to FIG. 17, in FIG. 18 the absorption layer 5 does not completely cover the substrate 1. However, the matching layer 4 is completely covered by the absorption layer 5.

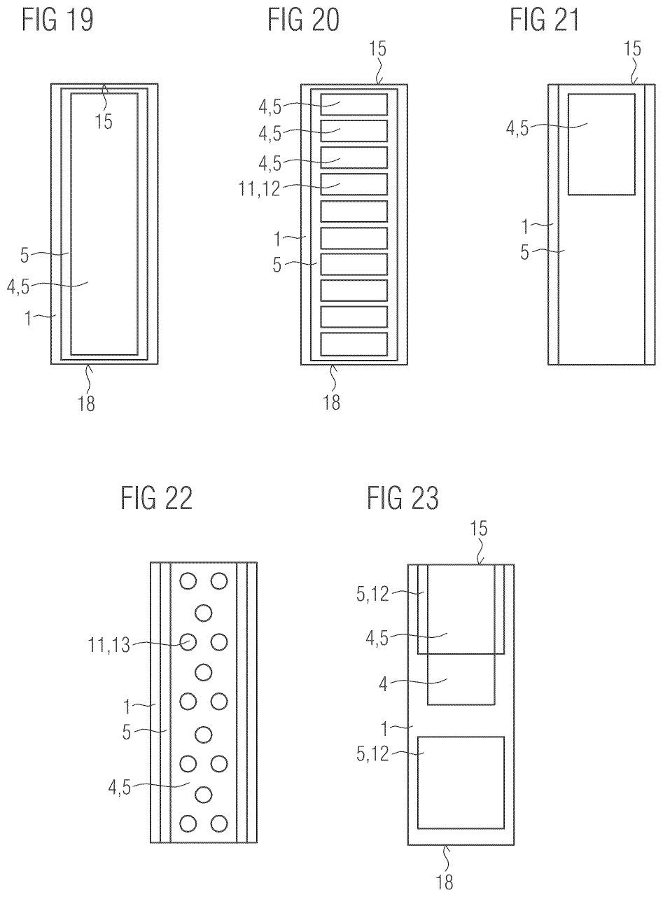

In FIG. 19, in contrast to FIG. 18, the matching layer 4 and the absorption layer 5 are laterally spaced from the light outcoupling facet 15 and the back side facet 18.

In contrast to the edge-emitting semiconductor diode in FIG. 19, the matching layer 4 in FIG. 20 comprises an additional lateral structuring 11. In particular, the matching layer 4 comprises a plurality of mutually separated segments 12 arranged along a direction between the light outcoupling facet 15 and the back side facet 18.

In the edge-emitting semiconductor laser diode in FIG. 21, compared to FIG. 17, only a sub-region of the second main surface 7 at the light outcoupling facet 18 is covered by the matching layer 4.

In contrast to the edge-emitting semiconductor laser diode of FIG. 20, the edge-emitting semiconductor laser diode in FIG. 22 comprises a lateral structuring 11 of the matching layer 4 in the form of a plurality of cut-outs 13.

The edge-emitting semiconductor laser diode in FIG. 23 comprises an absorption layer 5 comprising two segments 12 separated from each other. The two segments 12 are arranged in the vicinity of the light outcoupling facet 15 and the back side facet, while the matching layer 4 covers a region of the second main surface 7 adjacent to the light outcoupling facet 15.

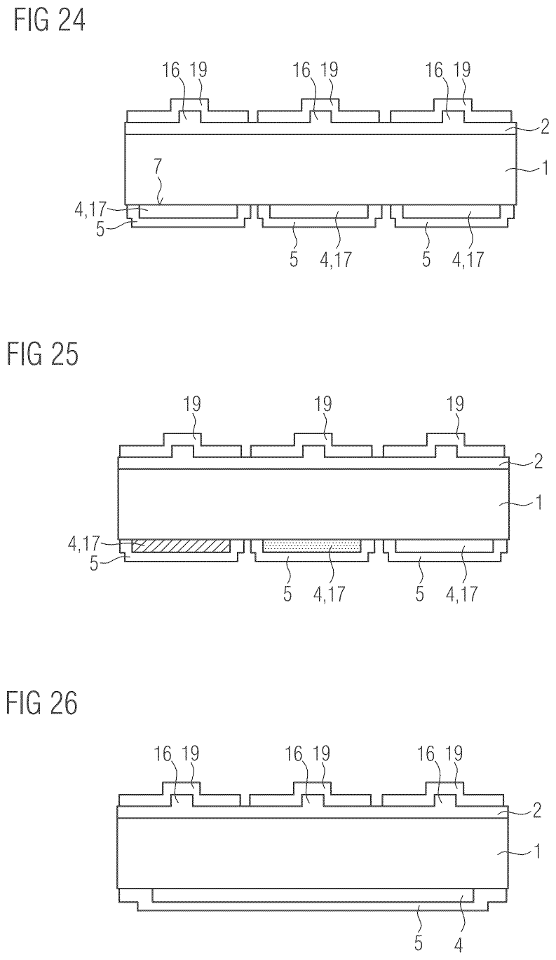

FIG. 24 shows a top view of the light outcoupling facet 15 of an edge-emitting semiconductor laser diode. The epitaxial semiconductor layer stack 2 comprises three laterally spaced emission regions 16. The three emission regions 16 are electrically contacted independently of one another by separate contact layers 19 and can thus be controlled and/or operated independently of one another. For each emission region 16, an associated sub-region 17 of the matching layer 4 and the absorption layer 5 is applied to the second main surface 7 of the substrate 1, which is arranged directly opposite to the respective emission region 16.

In contrast to FIG. 24, the sub-regions 17 of the matching layer 4 in the edge-emitting semiconductor laser diode in FIG. 25 comprise different properties. For example, the matching layer 4 comprises different thicknesses D and/or different material compositions in the sub-regions 17. Thus, the matching layer 4 in the sub-regions 17 can be adapted, for example, to different emission wavelengths of the different emission regions 16.

FIG. 26 shows an edge-emitting semiconductor laser diode which, in contrast to FIG. 24, comprises a continuous matching layer 4. In particular, the matching layer 4 is not divided into separate sub-regions 17. Thus, all emission regions 16 of the semiconductor layer stack 2 share a common matching layer 4.

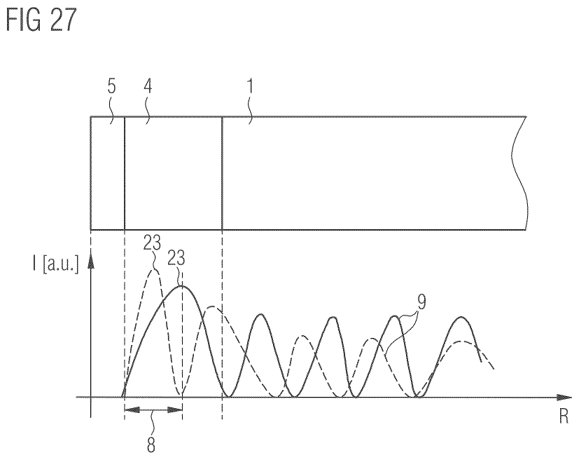

FIG. 27 shows a schematic representation of an intensity I of substrate modes 9 in a direction R perpendicular to the second main surface 7 of the substrate 1. The substrate modes 9 are shown in this direction R as standing electromagnetic waves. At the interface between the matching layer 4 and the metallic absorption layer 5, the substrate modes 9 comprise in particular, a node at which the intensity I of the substrate modes 9 disappears. The matching layer 4 moves the intensity maxima 23 of the substrate modes 9 closer to the absorption layer 5. This advantageously increases the attenuation of the substrate modes 9 by the absorption layer 5.

The invention is not limited to the exemplary embodiments by the description thereof. Rather, the invention includes any new feature as well as any combination of features, which includes, in particular, any combination of features in the patent claims, even if this feature or combination itself is not explicitly stated in the patent claims or exemplary embodiments.

1. An edge-emitting semiconductor laser diode, comprising:
a substrate with a first main surface and a second main surface opposite to the first main surface,
an epitaxial semiconductor layer stack on the first main surface of the substrate, wherein the epitaxial semiconductor layer stack comprises an active layer for generating electromagnetic radiation,
at least one matching layer arranged on the second main surface of the substrate, and
an absorption layer disposed directly on the matching layer and configured for absorbing the electromagnetic radiation at least partially, wherein
the substrate and the matching layer are transparent to electromagnetic radiation generated during operation, and
the matching layer is configured for increasing the absorption of electromagnetic radiation in the absorption layer.

2. The edge-emitting semiconductor laser diode according to claim 1, wherein the substrate is a growth substrate for the epitaxial semiconductor layer stack.

3. The edge-emitting semiconductor laser diode according to claim 1, wherein the matching layer reduces a distance between the absorption layer and an intensity maximum of electromagnetic laser modes propagating in the substrate.

4. The edge-emitting semiconductor laser diode according to claim 1, wherein the matching layer reduces a reflection of electromagnetic laser modes propagating in the substrate at the absorption layer.

5. The edge-emitting semiconductor laser diode according to claim 1, wherein a refractive index of the matching layer for electromagnetic radiation generated during operation is larger than a refractive index of the substrate for electromagnetic radiation generated during operation.

6. The edge-emitting semiconductor laser diode according to claim 1, wherein an extinction coefficient of the matching layer for electromagnetic radiation generated during operation is at most 2.

7. (canceled)

8. The edge-emitting semiconductor laser diode according to claim 1, wherein a thickness (D) of the matching layer is D=D₀+m*Δd with a tolerance of +30 nanometers, wherein
$${D}_{0} = \frac{λ}{450 * ( 0.00192 * {n}^{2} + 0.01873 * n - 0.05235 )} ,$$
$$Δ d = \frac{λ}{\sqrt[2]{{n}^{2} - {n}_{Substrate}^{2}}} ,$$
m denotes an integer larger than or equal to zero, λ denotes a wavelength of electromagnetic radiation generated during operation, n denotes a refractive index of the matching layer for electromagnetic radiation generated during operation, and n_{Substrate} denotes a refractive index of the substrate for electromagnetic radiation generated during operation.

9. The edge-emitting semiconductor laser diode according to claim 1, wherein the matching layer comprises a lateral structuring such that only a part of the second main surface of the substrate is covered by the matching layer and/or the matching layer comprises at least two segments separated from each other and/or the matching layer comprises at least one cut-out.

10. The edge-emitting semiconductor laser diode according to claim 1, wherein the matching layer comprises titanium oxide, non-stoichiometric silicon oxide, non-stoichiometric silicon nitride, silicon carbide, or gallium phosphide.

11. The edge-emitting semiconductor laser diode according to claim 1, wherein the matching layer is electrically conductive.

12. The edge-emitting semiconductor laser diode according to claim 1, wherein the absorption layer is configured as a contact layer for electrical contacting of the epitaxial semiconductor layer stack.

13. The edge-emitting semiconductor laser diode according to claim 1, wherein the absorption layer comprises a metal, a semiconductor material, or a non-stoichiometric dielectric.

14. The edge-emitting semiconductor laser diode according to claim 1, additionally comprising a light blocking layer arranged on a sub-region of a light outcoupling facet of the semiconductor laser diode and configured for at least partially absorbing and/or reflecting electromagnetic laser modes propagating in the substrate.

15. The edge-emitting semiconductor laser diode according to claim 1, wherein the active layer comprises at least two emission regions arranged laterally next to each other, which are configured for generating electromagnetic radiation in different wavelength ranges.

16. The edge-emitting semiconductor laser diode according to claim 15, wherein the matching layer comprises at least two sub-regions arranged laterally next to each other and wherein one sub-region each is arranged in a direction perpendicular to the first main surface of the substrate under an emission region, respectively.

17. The edge-emitting semiconductor laser diode according to claim 16, wherein the sub-regions of the matching layer comprise different materials and/or different thicknesses.
